(19) United States
(12) Patent Application Publication
(10) Pub. No.: US 2026/0351857 A1
(43) Pub. Date: Nov. 5, 2026

(54) INTELLIGENT REFLECTING SURFACE

(71) Applicant: Japan Display Inc., Tokyo (JP)

(72) Inventors: Mitsutaka OKITA, Tokyo (JP); Shinichiro OKA, Tokyo (JP); Daiichi SUZUKI, Tokyo (JP); Kazuki MATSUNAGA, Tokyo (JP)

(73) Assignee: Japan Display Inc., Tokyo (JP)

(21) Appl. No.: 19/709,529

(22) Filed: Jun. 16, 2026

Related U.S. Application Data
(63) Continuation of application No. PCT/JP2024/038704, filed on Oct. 30, 2024.

(30) Foreign Application Priority Data
Dec. 28, 2023 (JP) 2023-223625

(51) Int. Cl. H01Q 15/00; H10K 59/121

(52) U.S. Cl. CPC H01Q 15/002; H10K 59/1213

(57) ABSTRACT

An intelligent reflecting surface includes a plurality of reflective elements arranged at predetermined intervals in a first direction and a second direction intersecting the first direction, and a plurality of light-emitting elements arranged in a region between the plurality of reflective elements. Each of the plurality of reflective elements includes a patch electrode arranged on a first substrate, a ground electrode arranged on a second substrate facing the first substrate and superimposed on the patch electrode, and a liquid crystal layer between the patch electrode and the ground electrode. Each of the plurality light-emitting elements includes a first electrode provided on the first substrate, a second electrode provided on the first substrate, and an organic light-emitting layer sandwiched between the first electrode and the second electrode.

### CROSS-REFERENCE TO RELATED APPLICATIONS

This application is a Continuation of International Patent Application No. PCT/JP2024/038704, filed on Oct. 30, 2024, which claims the benefit of priority to Japanese Patent Application No. 2023-223625, filed on Dec. 28, 2023, the entire contents of each are incorporated herein by reference.

### FIELD

One embodiment of the present invention relates to an intelligent reflecting surface capable of controlling the traveling direction of reflected radio waves. In particular, one embodiment of the present invention relates to an intelligent reflecting surface having an image display function.

### BACKGROUND

In the field of wireless communication, communication using a phased array antenna is being studied in fifth-generation communication (5G) for achieving high-speed and large-capacity communication. A phased array antenna device controls directivity while the antenna is fixed by adjusting the amplitude and phase of high-frequency signals applied to each of a plurality of antenna elements arranged in a planar configuration. The phased array antenna device requires a phase shifter. A phased array antenna device using a phase shifter that utilizes changes in the dielectric constant due to the alignment status of liquid crystal has been disclosed (for example, see Japanese Laid-Open Patent Publication No. H11-103201).

### SUMMARY

An intelligent reflecting surface according to one embodiment of the present invention includes a plurality of reflective elements arranged at predetermined intervals in a first direction and a second direction intersecting the first direction, and a plurality of light-emitting elements arranged in a region between the plurality of reflective elements, wherein each of the plurality of reflective elements includes a patch electrode arranged on a first substrate, a ground electrode arranged on a second substrate facing the first substrate and superimposed on the patch electrode, and a liquid crystal layer between the patch electrode and the ground electrode, wherein each of the plurality of light-emitting elements includes a first electrode provided on the first substrate, a second electrode provided on the first substrate, and an organic light-emitting layer sandwiched between the first electrode and the second electrode.

An intelligent reflecting surface according to one embodiment of the present invention includes a plurality of reflective elements arranged at predetermined intervals in a first direction and a second direction intersecting the first direction, and a plurality of light-emitting elements arranged in a region between the plurality of reflective elements, wherein each of the plurality of reflective elements includes a drive electrode arranged on a first substrate and a patch electrode arranged on a second substrate facing the first substrate and superimposed on the drive electrode, and a liquid crystal layer between the drive electrode and the patch electrode, wherein each of the plurality of light-emitting elements includes a first electrode provided on the first substrate, a second electrode provided on the first substrate, and an organic light-emitting layer sandwiched between the first electrode and the second electrode.

### BRIEF DESCRIPTION OF DRAWINGS

FIG. 1 shows a plan view of a reflective element used in an intelligent reflecting surface according to one embodiment of the present invention.

FIG. 2 shows a cross-sectional structure between A1-A2 shown in the plan view of a reflective element used in an intelligent reflecting surface according to one embodiment of the present invention.

FIG. 3 shows a state in which no voltage is applied between a patch electrode and a ground electrode in two states when a reflective element used in an intelligent reflecting surface according to one embodiment of the present invention operates.

FIG. 4 shows a state in which a voltage is applied between a patch electrode and a ground electrode in two states when a reflective element used in an intelligent reflecting surface according to one embodiment of the present invention operates.

FIG. 5 shows a configuration of an intelligent reflecting surface according to one embodiment of the present invention.

FIG. 6 is a diagram schematically showing that the traveling direction of a reflected wave is changed by an intelligent reflecting surface according to one embodiment of the present invention.

FIG. 7 shows an enlarged view of the 2-row×2-column reflective elements and a plurality of pixels shown in FIG. 5.

FIG. 8 is a circuit diagram of an intelligent reflecting surface.

FIG. 9 is a cross-sectional view showing a configuration of a reflector plate unit cell and pixels.

FIG. 10 is a planar layout diagram showing an enlarged portion of reflective elements and common electrodes of pixels.

FIG. 11 is a layout diagram of a reflector plate unit cell and pixels when viewed from the dielectric substrate side.

FIG. 12 is a cross-sectional view showing a configuration of a reflector plate unit cell and pixels.

FIG. 13 is a planar layout diagram of a patch electrode when viewed from a counter substrate side.

FIG. 14 is a planar layout diagram showing an enlarged portion of a reflective element and a common electrode of pixels.

FIG. 15 is a planar layout diagram showing an enlarged portion of a reflective element and a common electrode of pixels.

### DESCRIPTION OF EMBODIMENTS

In mobile communication, there is a problem that communication conditions deteriorate in places where users are densely gathered, such as in front of stations or event venues. In addition, large displays are installed in such places where many people gather, and advertisements and various information are provided. In places where many people gather like this, both radio wave reflector plates such as phased array antennas and information display devices may be installed.

### However, it Is Difficult to Secure a Place for Installing Both the Radio Wave Reflector Plate and

the information display device. In addition, since the information display device reflects radio waves, they may affect the control of the communication area using the radio wave reflector plate.

Hereinafter, embodiments of the present invention will be described with reference to the drawings and the like. However, the present invention can be implemented in many different aspects, and should not be construed as being limited to the description of the embodiments exemplified below. The width, thickness, shape, and the like of each part may be schematically represented in comparison with the actual embodiments in order to clarify the description, but the drawings are merely examples and do not limit the interpretation of the present invention. Furthermore, in the present specification and drawings, elements similar to those previously described with respect to the preceding figures may be denoted by the same reference signs (or reference signs denoted by a, b, and the like added after a number) and detailed descriptions may be omitted as appropriate. In addition, the terms “first” and “second” appended to each element are convenient labels used to distinguish each element and have no further meaning unless specifically explained.

In the case where a member or region is to be “on (or under)” another member or region in the present specification, this includes not only the case where it is directly above (or directly below) the other member or region, but also the case where it is above (or below) the other member or region, that is, it is also includes the case where another component is included in above (or below) the other member or region.

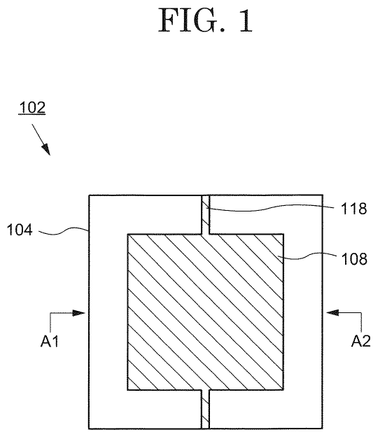

An intelligent reflecting surface according to one embodiment of the present invention will be described with reference to FIG. 1 to FIG. 11. In addition, the intelligent reflecting surface according to the present embodiment can also be called a liquid crystal reflecting surface, a reflect array, or a liquid crystal meta surface reflecting surface.

### 1. Reflective Element

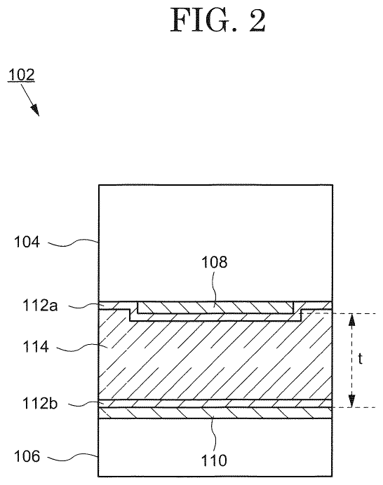

First, a structure of a reflective element 102 used in the intelligent reflecting surface will be described with reference to FIG. 1 to FIG. 4. FIG. 1 and FIG. 2 show the reflective element 102 used in the intelligent reflecting surface according to one embodiment of the present invention. FIG. 1 shows a plan view when the reflective element 102 is viewed from above (the side where radio waves are incident), and FIG. 2 shows a cross-sectional view between A1-A2 shown in the plan view.

As shown in FIG. 1 and FIG. 2, the reflective element 102 includes at least a patch electrode 108, a ground electrode 110, and a liquid crystal layer 114. The reflective element 102 may further include a dielectric substrate 104, a counter substrate 106, a first alignment film 112a, and a second alignment film 112b. Within the reflective element 102, the dielectric substrate 104 can also be regarded as a single dielectric layer. The patch electrode 108 is provided on the dielectric substrate 104, and the ground electrode 110 is provided on the counter substrate 106. The first alignment film 112a is provided on the dielectric substrate 104 to cover the patch electrode 108, and the second alignment film 112b is provided on the counter substrate 106 to cover the ground electrode 110. The patch electrode 108 and the ground electrode 110 are arranged to face each other, and the liquid crystal layer 114 is provided therebetween. The first alignment film 112a is interposed between the patch electrode 108 and the liquid crystal layer 114, and the second alignment film 112b is interposed between the ground electrode 110 and the liquid crystal layer 114.

The patch electrode 108 preferably has a shape that is symmetrical with respect to the vertically polarized and horizontally polarized waves of the incident radio wave, and has a square or circular shape in a plan view. FIG. 1 shows the case where the patch electrode 108 has a square shape in a plan view. The shape of the ground electrode 110 is not particularly limited and has a shape extending over substantially the entire surface of the counter substrate 106 to have a larger area than the patch electrode 108. The material forming the patch electrode 108 and the ground electrode 110 is not limited, and they may be formed using a conductive metal or metal oxide. A first wiring 118 may be provided on the dielectric substrate 104. The first wiring 118 is connected to the patch electrode 108. The first wiring 118 is used when applying a control signal to the patch electrode 108. In addition, the first wiring 118 is used to connect a certain patch electrode to an adjacent patch electrode when a plurality of reflective elements 102 is arranged.

Although not shown in FIG. 1 and FIG. 2, the dielectric substrate 104 and the counter substrate 106 are bonded together with the sealing material. The dielectric substrate 104 and the counter substrate 106 are arranged facing each other with a gap therebetween, and the liquid crystal layer 114 is provided in a region surrounded by the sealing material. The liquid crystal layer 114 is provided to fill the gap between the dielectric substrate 104 and the counter substrate 106. The gap between the dielectric substrate 104 and the counter substrate 106 is 20 μm to 100 μm, and is for example, 50 μm. Since the patch electrode 108, the ground electrode 110, the first alignment film 112a, and the second alignment film 112b are provided between the dielectric substrate 104 and the counter substrate 106, the gap between the first alignment film 112a and the second alignment film 112b provided on each of the dielectric substrate 104 and the counter substrate 106 is the thickness of the liquid crystal layer 114. Although not shown in FIG. 2, a spacer may be provided between the dielectric substrate 104 and the counter substrate 106 to keep the gap constant.

The control signal for controlling the alignment of liquid crystal molecules of the liquid crystal layer 114 is applied to the patch electrode 108. The control signal is a DC voltage signal or a polarity inversion signal in which a positive DC voltage and a negative DC voltage are alternately inverted. A voltage at an intermediate level voltage of the ground or polarity inversion signal is applied to the ground electrode 110. When the control signal is applied to the patch electrode 108, the alignment status of the liquid crystal molecules contained in the liquid crystal layer 114 changes. A liquid crystal material having dielectric anisotropy is used for the liquid crystal layer 114. For example, a nematic liquid crystal, a smectic liquid crystal, a cholesteric liquid crystal, or a discotic liquid crystal can be used as the liquid crystal layer 114. The dielectric constant of the liquid crystal layer 114 with dielectric anisotropy changes due to a change in the alignment status of the liquid crystal molecules. The reflective element 102 can change the dielectric constant of the liquid crystal layer 114 by the control signal applied to the patch electrode 108, and the phase of the reflected wave can be delayed when reflecting radio waves.

The frequency bands of the radio waves reflected by the reflective element 102 are a very high frequency (VHF) band, an ultra-high frequency (UHF) band, a microwave (SHF: Super High Frequency) band, a sub-millimeter wave (THF: Tremendously High Frequency) band, and a millimeter wave (EHF: Extra High Frequency) band. The alignment of the liquid crystal molecules of the liquid crystal layer 114 changes in response to the control signal applied to the patch electrode 108, but hardly follows the frequency of the radio wave irradiated onto the patch electrode 108. Therefore, the reflective element 102 can control the phase of the reflected radio wave without being affected by the radio wave.

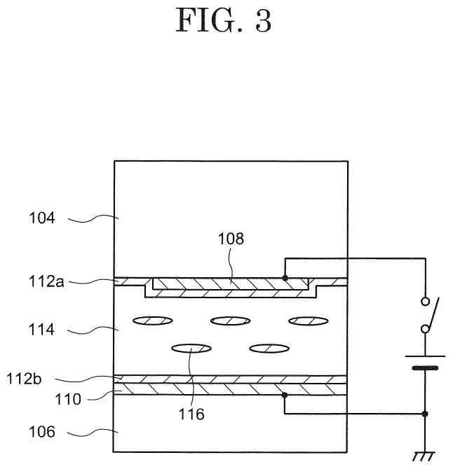

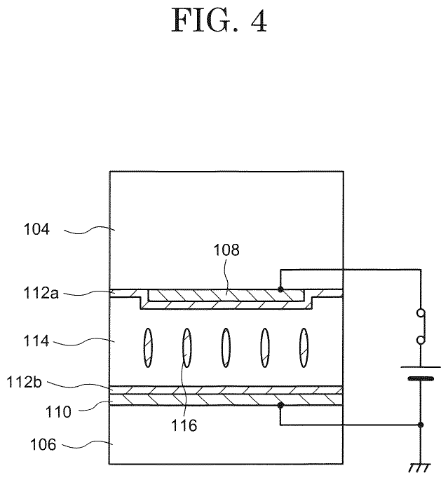

FIG. 3 Shows a State in Which No Voltage Is Applied Between the Patch Electrode 108 and the ground electrode 110 (referred to as a “first state”). FIG. 3 shows the case where the first alignment film 112a and the second alignment film 112b are horizontal alignment films. The long axis oaf liquid crystal molecule 116 in the first state is aligned horizontally with respect to the surfaces of the patch electrode 108 and the ground electrode 110 by the first alignment film 112a and the second alignment film 112b. FIG. 4 shows a state in which the control signal (voltage signal) is applied to the patch electrode 108 (referred to as a “second state”). In the second state, the long axis of the liquid crystal molecule 116 is aligned perpendicular to the surfaces of the patch electrode 108 and the ground electrode 110 due to the action of an electric field. The angle at which the long axes of the liquid crystal molecule 116 is aligned can also be adjusted to a direction intermediate between the horizontal direction and the vertical direction, depending on the magnitude of the control signal applied to the patch electrode 108 (the magnitude of the voltage between the counter electrode and the patch electrode).

In the case where the liquid crystal molecule 116 has positive dielectric anisotropy, the dielectric constant of the second state is greater than that of the first state. Furthermore, in the case where the liquid crystal molecule 116 has negative dielectric anisotropy, the apparent dielectric constant of the second state is smaller than that of the first state. The liquid crystal layer 114 having dielectric anisotropy can also be regarded as a variable dielectric layer. The reflective element 102 can be controlled to delay (or not delay) the phase of the reflected wave by utilizing the dielectric anisotropy of the liquid crystal layer 114.

The reflective element 102 is used in a radio wave reflector plate that reflects radio waves in a predetermined direction. It is preferable that the reflective element 102 does not attenuate the amplitude of reflected radio waves as much as possible. As is clear from the structure shown in FIG. 2, when radio waves propagating through the air are reflected by the reflective element 102, the radio waves pass through the dielectric substrate 104 twice. For example, the dielectric substrate 104 is formed of a dielectric material such as glass or resin.

### 2. Intelligent Reflecting Surface

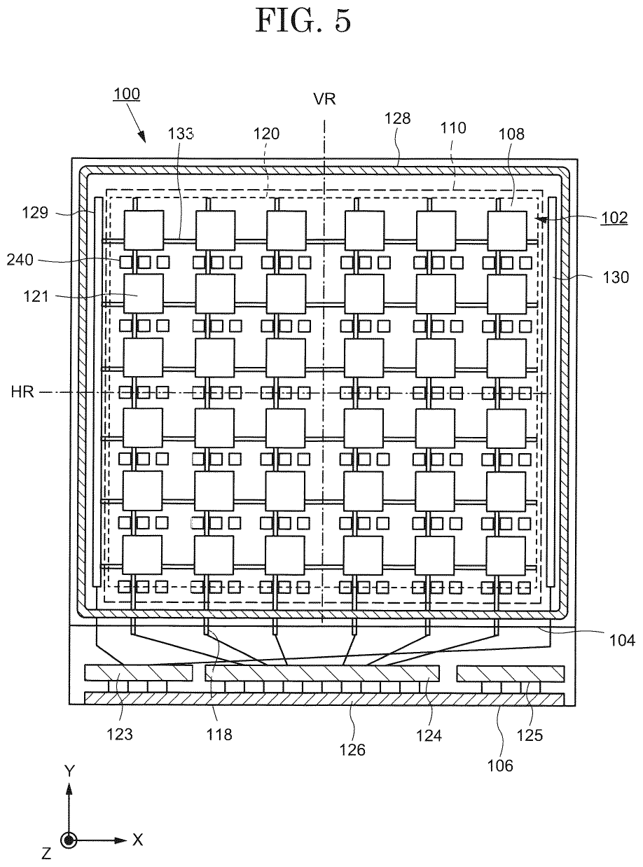

Next, an intelligent reflecting surface 100 in which the reflective elements 102 are integrated will be described. The intelligent reflecting surface 100 according to one embodiment of the present invention will be described with reference to FIG. 5 to FIG. 11. The intelligent reflecting surface 100 according to one embodiment of the present invention has not only a radio wave reflecting function but also an image display function. First, the radio wave reflecting function of the intelligent reflecting surface 100 will be described.

### 2-1. Radio Wave Reflecting Function (Biaxial Reflection Control)

FIG. 5 shows a configuration of the intelligent reflecting surface 100 according to one embodiment of the present invention. In the present embodiment, the radio wave reflecting function of the intelligent reflecting surface 100 capable of biaxial reflection control will be described.

The intelligent reflecting surface 100 includes a radio wave reflector plate 120. The radio wave reflector plate 120 is composed of a plurality of reflector plate unit cells 121. The reflector plate unit cell 121 is composed of the reflective element 102 and a switching element (also referred to as a transistor) that controls the reflective element 102. For example, the plurality of reflective elements 102 is arranged in a row direction (an X-axis direction shown in FIG. 5) and a column direction (a Y-axis direction shown in FIG. 5) that intersects the row direction. The reflective element 102 is arranged so that the patch electrode 108 faces the incident surface of the radio waves. The radio wave reflector plate 120 has a flat plate shape, and a plurality of patch electrodes 108 is arranged in a matrix within the in-plane of the flat pate-shaped surface.

The intelligent reflecting surface 100 has a structure in which the plurality of reflective elements 102 are integrated on a single dielectric substrate 104. As shown in FIG. 5, the intelligent reflecting surface 100 has a structure including the dielectric substrate 104 on which the plurality of patch electrodes 108 is arranged, the counter substrate 106 on which the ground electrode 110 is provided are arranged to overlap the dielectric substrate 104, and a liquid crystal layer (not shown) is provided between the dielectric substrate 104 and the counter substrate 106. The radio wave reflector plate 120 is formed in a region where the plurality of patch electrodes 108 and the ground electrode 110 overlap. A cross-sectional structure of the radio wave reflector plate 120 is the same as the structure of the reflective element 102 shown in FIG. 2 when viewed for each patch electrode 108. The dielectric substrate 104 and the counter substrate 106 are bonded together with a sealing material 128, and the liquid crystal layer (not shown) is provided in a region inside the sealing material 128.

As described above, the reflector plate unit cells 121 are arranged on the dielectric substrate 104 in the X-axis direction and the Y-axis direction. In addition, a plurality of scan lines 133 extending in the X-axis direction and a plurality of signal lines 132 extending in the Y-axis direction are arranged on the dielectric substrate 104. Each of the plurality of scan lines 133 is electrically connected to the plurality of patch electrodes 108 arranged in the X-axis direction. In other words, the plurality of patch electrodes 108 arranged in the X-axis direction is connected by the scan line 133. Each of the plurality of signal lines 132 is electrically connected to the plurality of patch electrodes 108 arranged in the Y-axis direction. In other words, the plurality of patch electrodes 108 arranged in the Y-axis direction is connected by the signal line 132.

The dielectric substrate 104 includes, in addition to a region facing the counter substrate 106, a peripheral region 122 extending outside the counter substrate 106. A first driver IC 123, a second driver IC 124, and a third driver IC 125 are provided in the peripheral region 122. A terminal part 126 is a region that forms a connection with an external circuit, and for example, a flexible printed circuit substrate (not shown) is connected thereto. Signals for controlling each of the first driver IC 123, the second driver IC 124, and the third driver IC 125 are input from the flexible printed circuit substrate to the terminal part 126.

In addition, a first drive circuit 129 and a second drive circuit 130 are provided in the region inside the sealing material 128. The first drive circuit 129 and the second drive circuit 130 are connected to the first driver IC 123. The first drive circuit 129 is connected to the plurality of scan lines 133 and outputs a scanning signal to each of the plurality of scan lines 133. The second driver IC 124 is connected to the plurality of signal lines 132 and outputs control signals with different voltage levels to each of the plurality of signal lines 132. The plurality of scan lines 133 and the plurality of signal lines 132 are arranged to intersect each other with an insulating layer (not shown) interposed therebetween. In addition, the first driver IC 123 and the third driver IC 125 control pixels, which will be described later.

The intelligent reflecting surface 100 shown in FIG. 5 can control the traveling direction of the reflected wave in the left-right direction of the drawing about a reflection axis VR parallel to the Y-axis direction for radio waves irradiated onto the radio wave reflector plate 120, and can also control the traveling direction of the reflected wave in the up-down direction of the drawing about a reflection axis HR parallel to the X-axis direction. That is, the intelligent reflecting surface 100 has the reflection axis VR parallel to the Y-axis direction and the reflection axis HR parallel to the X-axis direction, so that the intelligent reflecting surface 100 can control the reflection angle in a direction with the reflection axis VR as the rotation axis and in a direction with the reflection axis HR as the rotation axis.

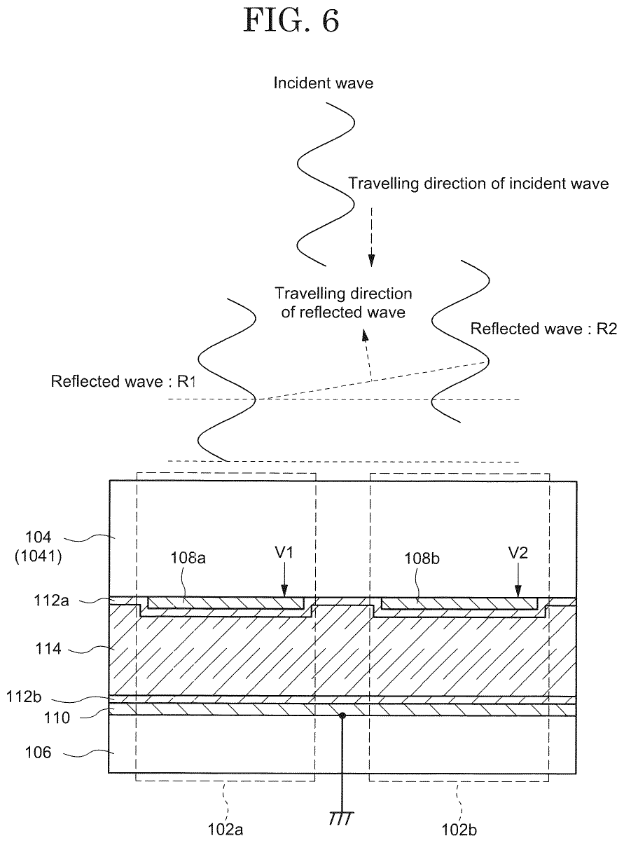

FIG. 6 is a schematic diagram showing a change in the traveling direction of a reflected wave by two reflective elements 102. This shows the case where, when the radio wave is incident on a reflective element 102a and a reflective element 102b at the same phase, the phase change of the reflected wave by the reflective element 102b is larger than that by the reflective element 102a because different control signals (V1≠V2) are applied to the reflective element 102a and the reflective element 102b. As a result, the phase of the reflected wave R1 reflected by the reflective element 102a is different from the phase of the reflected wave R2 reflected by the reflective element 102b (in FIG. 6, the phase of the reflected wave R2 is advanced from the phase of the reflected wave R1), and apparently, the traveling direction of the reflected wave changes in an oblique direction.

Furthermore, in FIG. 6, since the plurality of patch electrodes 108 arranged in the Y-axis direction is electrically connected by the signal line 132 and electrically equipotential, it is also conceivable to replace them with strip-shaped electrodes continuous in the Y-axis direction rather than a shape divided into a plurality of parts. However, since the dimensions of the patch electrode 108 have an appropriate range depending on the wavelength of the reflected radio waves, if the electrode is made into a strip shape, the sensitivity to the target wavelength decreases, and the behavior with respect to vertical polarization and horizontal polarization will be different. Therefore, as shown in FIG. 6, it is preferable to arrange the patch electrodes 108 in an array with a shape symmetrical with respect to vertical polarization and horizontal polarization (FIG. 6 shows a square, but it may be circular), and to connect the plurality of patch electrodes 108 arranged parallel to the reflection axis VR with the signal line 132.

By applying such a principle to the intelligent reflecting surface 100 shown in FIG. 5, for example, by independently controlling the amount of phase change by the reflective elements for both rows and columns, the reflection direction can be controlled in uniaxial and biaxial directions.

### 2-2. Image Display Function

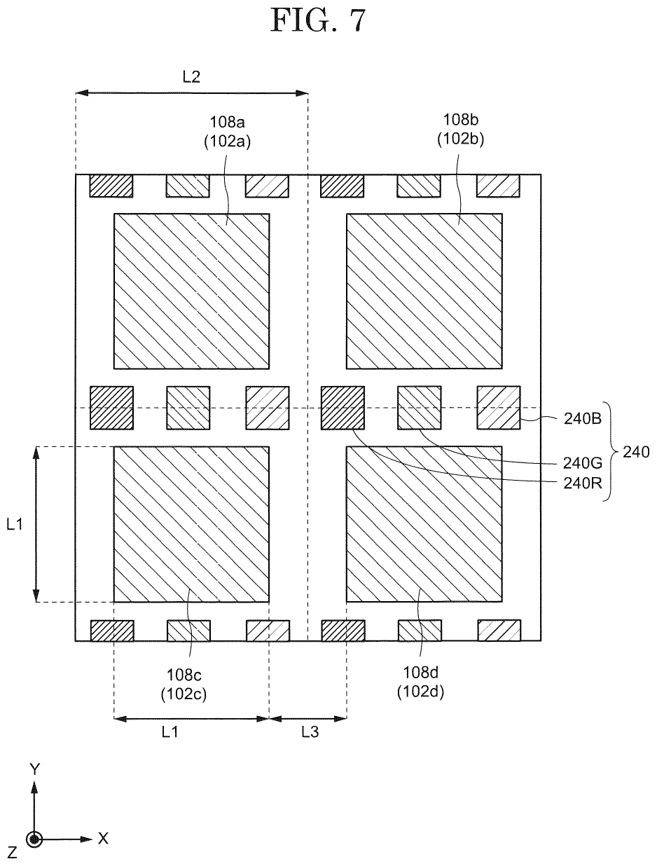

Next, the image display function of the intelligent reflecting surface 100 will be described with reference to FIG. 7 to FIG. 11. The intelligent reflecting surface 100 shown in FIG. 5 has the image display function. Specifically, a plurality of pixels 240 is provided in the gap between adjacent reflective elements 102. By controlling the plurality of pixels 240, an image can be displayed in the intelligent reflecting surface 100.

FIG. 7 shows an enlarged view of the 2-row×2-column reflective elements 102 and the plurality of pixels 240 shown in FIG. 5. In FIG. 7, when describing each of the 2-row×2-column reflective elements 102 separately, they will be described as reflective elements 102a to 102d. In addition, each component of the reflective element 102 will also be described with a similar distinction.

In the reflective element 102, in the case where a length L1 of one side of the patch electrode 108 is, for example, 2.8 mm (the size of the patch electrode is, for example, 2.8 mm×2.8 mm), and a pitch L2 of the patch electrode 108 is, for example, 3.7 mm, a gap L3 between adjacent patch electrodes 108 is 0.9 mm. In contrast, the pixel size is 200 μm² to 258700 μm² (for example, the RGB pixel size is 40 μm² to 500 μm², and a single-color pixel is 14 μm² to 170 μm²). Since the patch electrode 108 is smaller than the gap between adjacent patch electrodes 108, the plurality of pixels 240 can be provided in the gap between adjacent patch electrodes 108. Furthermore, in the case where the radio wave frequency is high and the pitch L is small, the upper limit of the pixel size may be smaller than 258700 μm².

The size of the pixel 240 is equivalent to the size of a light-emitting element 220. The size of the light-emitting element 220 can be appropriately selected in the range of 200 μm² to 258700 μm². In the gap between two adjacent patch electrodes 108, a plurality of light-emitting elements 220 may be arranged along the X-axis direction, the plurality of light-emitting elements 220 may be arranged along the Y-axis direction, or the plurality of light-emitting elements 220 may be arranged along each of the X-axis direction and the Y-axis direction. An example in which the plurality of pixels 240 having a size of several hundred μm² is arranged along the X-axis direction in the gap between the patch electrodes 108 will be described in FIG. 7. A region where the plurality of pixels 240 is provided in the gap between the patch electrodes 108 is also referred to as a display region.

The pixel 240 is a region corresponding to a display unit in which the brightness of one color element (for example, one of R (red), G (green), or B (blue)) can be controlled. Control of brightness in one pixel is performed by further dividing one pixel into a plurality of sub-pixels and controlling the brightness of each of the plurality of sub-pixels. The size of the pixel 240 or the size of the light-emitting element may differ depending on the color element. The pixel 240 is provided with a light-emitting element and a pixel circuit for driving the light-emitting element. For example, an organic EL element or an LED chip can be used as the light-emitting element. In the present embodiment, the case where the organic EL element is used as the light-emitting element will be described. The plurality of pixels 240 includes a pixel 240R representing red, a pixel 240G representing green, and a pixel 240B representing blue. When distinguishing each of the colors to be represented, the pixels 240R, 240G, and 240B will be used. In addition, each component of the pixel 240 will also be described with a similar distinction.

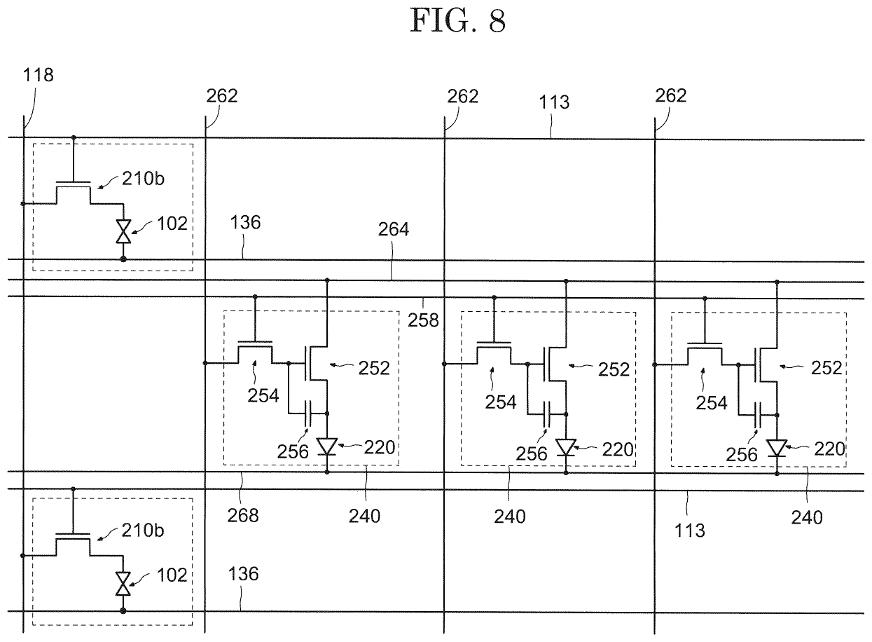

FIG. 8 is a circuit diagram of the reflector plate unit cell 121 and the pixel 240 provided in the intelligent reflecting surface 100. As shown in FIG. 8, the reflector plate unit cell 121 includes a transistor 210b and the reflective element 102. A gate electrode of the transistor 210b is connected to a scan line 113, a source electrode is connected to the first wiring 118, and a drain electrode is connected to the patch electrode of the reflective element 102. A common electrode 226 of the reflective element 102 is connected to a common wiring 136.

As shown in FIG. 8, three pixels 240 are arranged in the row direction. The pixel 240 includes elements such as a drive transistor 252, a select transistor 254, a storage capacitor 256, and the light-emitting element 220. A source electrode of the select transistor 254 is connected to a signal line 262, and a gate electrode of the select transistor 254 is connected to a scan line 258. A source electrode of the drive transistor 252 is connected to an anode power line 264, and a drain electrode of the drive transistor 252 is connected to one end of the light-emitting element 220. The other end of the light-emitting element 220 is connected to a cathode power line 268. A gate electrode of the drive transistor 252 is connected to a drain electrode of the select transistor 254. The storage capacitor 256 is connected to the gate electrode and the drain electrode of the drive transistor 252. A gradation signal that determines the light emission intensity of the light-emitting element 220 is supplied to the signal line 262 via the third driver IC 125. A scanning signal for selecting a pixel to which the gradation signal described above is written is supplied to the scan line 258 via the first driver IC 123 and the second drive circuit 130.

Although the case where the operations of the reflector plate unit cell 121 and the pixel 240 are controlled using the first driver IC 123 to the third driver IC 125 has been described in the present embodiment, the number of driver ICs is not particularly limited. The reflector plate unit cell 121 and the pixel 240 may be controlled using one driver IC.

### 3. Configuration of Intelligent Reflecting Surface 100a

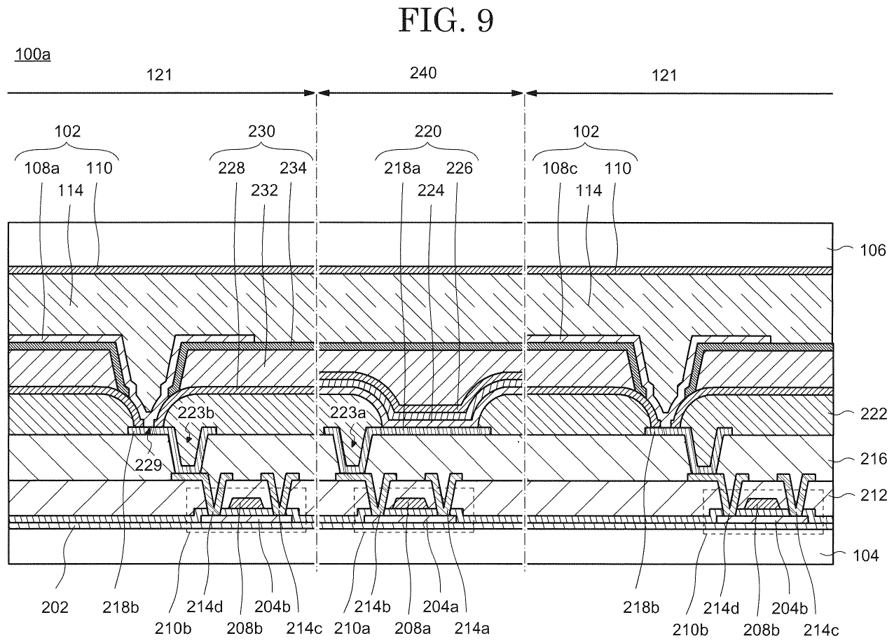

FIG. 9 is an example of a cross-sectional view of an intelligent reflecting surface 100a having the radio wave reflecting function and the image display function. In FIG. 9, the intelligent reflecting surface 100a in which the radio wave incident surface/reflecting surface is on the dielectric substrate 104 side and the light-emitting element 220 is also emitted from the dielectric substrate 104 side (bottom emission) will be described. In addition, FIG. 9 shows a region where the pixel 240 is provided between the regions where the adjacent reflector plate unit cells 121 are provided. As shown in FIG. 9, the reflective elements 102a and 102b, and the light-emitting element 220 are provided on the same substrate and in the region where the reflective element 102a and the reflective element 102b are separated from each other. A transistor for controlling the reflective element 102 and a transistor for controlling the light-emitting element 220 are also provided on the same substrate.

### 3-1. Configuration of Pixel

First, a configuration of the pixel 240 will be described. The pixel 240 includes a transistor 210a provided on the dielectric substrate 104 and the light-emitting element 220 provided on the transistor 210a.

A dielectric material such as a glass substrate, a quartz substrate, and a flexible substrate (polyimide, polyethylene terephthalate, polyethylene naphthalate, triacetyl cellulose, cyclic olefin copolymer, cycloolefin polymer, and other flexible resin substrates) can be used as the dielectric substrate 104 and the counter substrate 106. Since the intelligent reflecting surface 100a emits light of the light-emitting element 220 from the dielectric substrate 104 side, it is preferable to have light transmittance.

A base layer 202 is provided on the dielectric substrate 104. The base layer 202 is an insulating layer composed of inorganic materials such as silicon oxide, silicon nitride, and aluminum oxide. The base layer 202 is not limited to a single layer, and may have, for example, a stacked structure combining a silicon oxide layer and a silicon nitride layer. This configuration may be appropriately determined in consideration of adhesion to the dielectric substrate 104 and gas barrier properties against the transistors 210a and 210b described later.

The transistor 210a is provided on the base layer 202. The structure of the transistor 210a may be a top-gate type or a bottom-gate type. In FIG. 9, the transistor 210a is a top-gate type, and the transistor 210a includes a semiconductor layer 204a provided on the base layer 202, a gate insulating layer 206 covering the semiconductor layer 204a, and a gate electrode 208a provided on the gate insulating layer 206. Furthermore, an interlayer insulating layer 212 covering the gate electrode 208a is provided on the transistor 210a. In addition, a source electrode 214a and a drain electrode 214b are provided on the interlayer insulating layer 212. Each of the source electrode 214a and the drain electrode 214b is connected to the semiconductor layer 204a. Furthermore, although the interlayer insulating layer 212 is described as having a single-layer structure in the present embodiment, the interlayer insulating layer 212 may have a stacked structure.

The material of each layer forming the transistor 210a may be a known material and is not particularly limited. For example, polysilicon, amorphous silicon, or an oxide semiconductor can generally be used as the semiconductor layer 204a. The gate insulating layer 206 and the interlayer insulating layer 212 are configured with a single-layer structure or a stacked structure using a material similar to the base layer 202. The gate electrode 208a is composed of a metal material such as copper, molybdenum, tantalum, tungsten, and aluminum. The source electrode 214a and the drain electrode 214b are each composed of a metal material such as copper, titanium, molybdenum, and aluminum.

Although not shown in FIG. 9, the scan line 258 composed of the same metal material as the metal material forming the gate electrode 208a is provided in the same layer as the gate electrode 208a. Although not shown in FIG. 9, the signal line 262 extending in a direction intersecting the scan line 258 is provided in the same layer as the source electrode 214a and the drain electrode 214b.

A planarization film 216 is provided on the transistor 210. The planarization film 216 is composed of an organic resin material. For example, known organic resin materials such as polyimide, polyamide, acrylic, and epoxy can be used as the organic resin material. These materials have the feature that film formation is possible by a solution coating method, and the planarization effect is high. Although not particularly shown, the planarization film 216 is not limited to a single-layer structure and may have a stacked structure of a layer containing an organic resin material and an inorganic insulating layer.

A contact hole 223a that exposes a part of the drain electrode 214b is provided in the planarization film 216. The contact hole 223a is an opening for electrically connecting a pixel electrode 218a described later and the drain electrode 214b. Therefore, the contact hole 223a is provided overlapping a part of the drain electrode 214b. The drain electrode 214b is exposed at the bottom surface of the contact hole 223a.

The pixel electrode 218a is provided on the planarization film 216. The pixel electrode 218a is connected to the drain electrode 214b via the contact hole 223a provided in the planarization film 216. In the intelligent reflecting surface 100a, the pixel electrode 218a functions as an anode forming the light-emitting element 220. The configuration of the pixel electrode 218a differs depending on whether a top emission or bottom emission type is used. For example, in the case of the top emission type, a metal film with high light reflectance is used as the pixel electrode 218a, or a stacked structure of a transparent conductive layer with a high work function such as an indium oxide-based transparent conductive layer (for example, ITO) or a zinc oxide-based transparent conductive layer (for example, IZO, ZnO) and a metal film is used. On the other hand, in the case of the bottom emission type, an indium oxide-based transparent conductive layer or a zinc oxide-based transparent conductive layer is used as the pixel electrode 218a. FIG. 9 shows the bottom emission type, so that a transparent conductive layer is used as the pixel electrode 218a.

An insulating layer 222 composed of an organic resin material is provided on the pixel electrode 218a. Known resin materials such as polyimide-based, polyamide-based, acrylic-based, epoxy-based, or siloxane-based materials can be used as the organic resin material. The insulating layer 222 partially has an opening on the pixel electrode 218a. The insulating layer 222 is provided between the adjacent pixel electrodes 218a to cover the end portions (edge portions) of the pixel electrodes 218a, and functions as a member that separates the adjacent pixel electrodes 218a. For this reason, the insulating layer 222 is generally also referred to as a “partition” or “bank”. A part of the pixel electrode 218a exposed from the insulating layer 222 becomes a light-emitting region of the light-emitting element 220. It is preferable that the opening of the insulating layer 222 has an inner wall with a tapered shape. This can reduce coverage defects at the end portions of the pixel electrode 218a when forming a light-emitting layer described later. The insulating layer 222 may function not only to cover the end portions of the pixel electrode 218a but also as a filler that fills the concave parts caused by the contact holes of the planarization film 216.

An organic layer 224 is provided on the pixel electrode 218a. The organic layer 224 includes at least a light-emitting layer composed of an organic material and functions as a light-emitting part of the light-emitting element 220. The organic layer 224 may include, in addition to the light-emitting layer, various charge transport layers such as a hole injection layer and/or a hole transport layer, and an electron injection layer and/or an electron transport layer. The organic layer 224 is provided to cover the light-emitting region, that is, to cover the opening of the insulating layer 222 in the light-emitting region.

Furthermore, in the present embodiment, the organic layer 224 including a light-emitting layer that emits light of a desired color is provided, and the organic layer 224 including a different light-emitting layer is formed on each pixel electrode 218a, and the RGB colors are displayed. That is, in the present embodiment, the light-emitting layer of the organic layer 224 is discontinuous between adjacent pixel electrodes 218a. Although not shown, the hole injection layer and/or hole transport layer, and the electron injection layer and/or electron transport layer can be provided continuously between adjacent pixel electrodes 218a. Known structures and known materials can be used as the organic layer 224, and it is not particularly limited to the configuration of the present embodiment. In addition, the organic layer 224 may include a light-emitting layer that emits white light and displays each color of RGB through a color filter. In this case, the light-emitting layer may be provided continuously on the insulating layer 222. In this case, the color filter may be provided between the dielectric substrate 104 and the base layer 202.

The common electrode 226 is provided on the organic layer 224 and the insulating layer 222. The common electrode 226 functions as a cathode forming the light-emitting element 220. FIG. 9 shows the bottom emission type, so that a metal film with high light reflectance is used as the common electrode 226.

The organic layer 224 and the common electrode 226 are provided in common to the plurality of pixels 240. That is, the organic layer 224 and the common electrode 226 are provided on the entire display region. In FIG. 7, the display region corresponds to the plurality of pixels 240 arranged in the X direction. Therefore, the organic layer 224 and the common electrode 226 are provided in a strip shape in the X direction. In addition, the common electrode 226 is provided in each row to extend from the first drive circuit 129 to the second drive circuit 130 shown in FIG. 5. The common electrodes 226 provided in each row may be connected to each other in the vicinity of the first drive circuit 129 or in the vicinity of the second drive circuit 130. This can reduce the resistance of the common electrode 226.

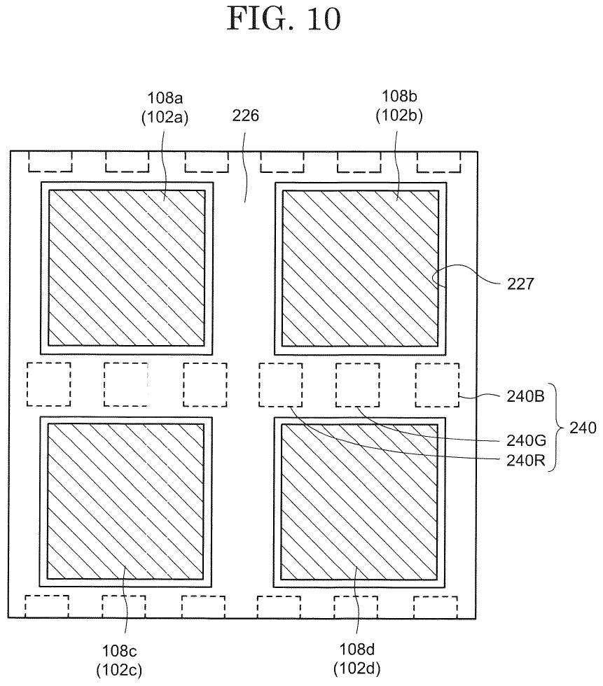

FIG. 10 is an enlarged view of reflective elements in 2 rows×2 columns and a plurality of pixels. As shown in FIG. 10, the pixel 240 is not provided in the gaps between the patch electrodes 108 in the Y-axis direction, but the common electrode 226 may be provided in the gaps between the patch electrodes 108 in the Y-axis direction. The common electrode 226 may have a grid-like shape that does not overlap the patch electrodes 108. In other words, in the common electrode 226, an opening 227 may be provided in a region overlapping the patch electrode 108. Although not shown, it is preferable that the organic layer 224 is also not provided in the region overlapping the patch electrode 108.

As shown in FIG. 9, an inorganic insulating layer 228, an organic insulating layer 232, and an inorganic insulating layer 234 are provided on the light-emitting element 220. The inorganic insulating layer 228, the organic insulating layer 232, and the inorganic insulating layer 234 function as a sealing layer 230 for preventing water and oxygen from entering the light-emitting element 220. By providing the sealing layer 230 on the light-emitting element 220, water and oxygen can be prevented from entering the light-emitting element 220, and the reliability of the light-emitting element 220 can be improved. For example, films such as silicon nitride, aluminum oxide, and aluminum nitride can be used as the inorganic insulating layer 228 and the inorganic insulating layer 234. In addition, an organic resin material such as polyimide resin, acrylic resin, epoxy resin, silicone resin, fluorine resin, or siloxane resin can be used as the organic insulating layer 232. Furthermore, the sealing film is not limited to the three layers of the inorganic insulating layer 228, the organic insulating layer 232, and the inorganic insulating layer 234 described above, and may be formed by appropriately combining the inorganic insulating layer and the organic insulating layer.

The organic material contained in the organic layer 224 is more likely to become an intrusion path for moisture and oxygen compared to the inorganic material. Therefore, it is preferable that the organic layer 224 is not exposed in the region where the intelligent reflecting surface 100a is in contact with air. However, the inorganic insulating material is less flexible than the organic material, and therefore prone to cracking. This crack may become the intrusion path for moisture and oxygen. Therefore, by providing the organic insulating layer 232 at least in the region where the light-emitting element 220 is provided and providing the inorganic insulating layer 228 and the inorganic insulating layer 234 in contact with each other in other regions, the intrusion of moisture and oxygen can be suppressed while maintaining the flexibility of the intelligent reflecting surface 100.

The above is the configuration of the pixel 240. Next, a configuration of the reflector plate unit cell 121 will be described. In the description of the reflector plate unit cell 121, descriptions of configurations similar to those of the pixel 240 may be omitted as appropriate.

### 3-2. Configuration of Reflector Plate Unit Cell

The reflector plate unit cell 121 includes the transistor 210b provided on the dielectric substrate 104 and the reflective element 102 provided on the transistor 210b. The reflective element 102 is provided above the light-emitting element 220.

The transistor 210b is formed through the same process as the transistor 210a. Therefore, configuration of the transistor 210b is similar to the configuration of the transistor 210a. The transistor 210b includes the semiconductor layer 204a provided on the base layer 202, the gate insulating layer 206 covering a semiconductor layer 204b, and a gate electrode 208b provided on the gate insulating layer 206. Furthermore, the interlayer insulating layer 212 covering the gate electrode 208b is provided on the transistor 210b. In addition, a source electrode 214c and a drain electrode 214d are provided on the interlayer insulating layer 212. Each of the source electrode 214c and the drain electrode 214d is connected to the semiconductor layer 204b.

In this case, the difference between the transistor 210b and the transistor 210a is the size of the transistor. The size of the transistor 210b is larger than the size of the transistor 210a. For example, while the channel width/channel length of the transistor 210a is 200 μm to 1200 μm/4 μm, the channel width/channel length of the pixel transistor 210b is 3 μm to 10 μm/10 μm to 200 μm. In the case of a display device using the organic EL element, a steady current of about several tens of nA is supplied to one pixel. In the saturation region, the channel length is large and the channel width is the minimum necessary to stably supply a small current. The size of the transistor 210a and the size of the transistor 210b can be appropriately set according to the size of the reflective element 102 and the size of the pixel 240.

Although not shown in FIG. 9, the scan line 133 composed of the same metal material as the metal material forming the gate electrode 208b is provided in the same layer as the gate electrode 208b. In addition, although not shown in FIG. 9, the signal line 132 extending in a direction intersecting the scan line 133 is provided in the same layer as the source electrode 214c and the drain electrode 214d. That is, the gate electrodes 208a and 208b, the scan line 258, and the scan line 133 are provided on the gate insulating layer 206. Furthermore, the source electrode 214a, the drain electrode 214b, the source electrode 214c, the drain electrode 214d, the signal line 262, and the signal line 132 are provided on the interlayer insulating layer 212.

A connection electrode 218b is provided on the planarization film 216. The connection electrode 218b is formed in the same process as the pixel electrode 218a. The connection electrode 218b is connected to the drain electrode 214d via a contact hole 223b provided in the planarization film 216. The insulating layer 222 is provided on the connection electrode 218b. An opening is provided in the insulating layer 222. The insulating layer 222 is also provided in the region where the reflector plate unit cell 121 is provided. As described above, the organic layer 224 and the common electrode 226 are not formed in the region where the patch electrode 108 is provided. This can reduce the effect of coupling between the patch electrode 218 and the transistor 210b.

The inorganic insulating layer 228 is provided in contact with the insulating layer 222. The inorganic insulating layer 228 covers the side surface of the opening of the insulating layer 222, and a contact hole 229 is provided to expose part of the surface of the connection electrode 218b. The organic insulating layer 232 is provided on the inorganic insulating layer 228. The organic insulating layer 232 is provided in a region overlapping the inorganic insulating layer 228. In addition, an end portion of the organic insulating layer 232 is provided in the vicinity of the opening of the insulating layer 222. By providing the organic insulating layer 232, the patch electrode 108 can be provided on a flat surface. The inorganic insulating layer 234 is provided on the organic insulating layer 232. The inorganic insulating layer 234 covers the end portion of the organic insulating layer 232 and contacts the inorganic insulating layer 228. This suppresses the intrusion of moisture from the end portion of the organic insulating layer 232. Furthermore, by providing the sealing layer 230, the effect of coupling between the patch electrode 218 and the transistor 210b can be reduced.

The patch electrode 108 is provided on the inorganic insulating layer 234. The patch electrode 108 contacts the inorganic insulating layer 228 and the inorganic insulating layer 234, and is connected to the connection electrode 218b. Although not shown, a first alignment film (corresponding to the first alignment film 112a shown in FIG. 1) is provided on the patch electrode 108 and the inorganic insulating layer 234.

The size of the patch electrode 108 is larger than the size of the pixel electrode. While the size of the patch electrode 108 is several mm², the size of the pixel electrode is several tens of μm² to several hundreds of μm². Therefore, when the size of the patch electrode 108 is 2.8 mm, it is 300 times to 40000 times the size of the pixel electrode.

The counter substrate 106 is provided to face the dielectric substrate 104. The ground electrode 110 is provided on the counter substrate 106. The ground electrode 110 is provided on the entire surface of the counter substrate 106. The ground electrode 110 is provided to overlap the patch electrodes 108 arranged in a matrix. The ground electrode 110 is also provided in a region overlapping the pixel 240 (the light-emitting element 220). Although not shown, the second alignment film 112b is provided on the surface of the ground electrode 110. The dielectric substrate 104 and the counter substrate 106 are arranged facing each other with a gap therebetween, and the liquid crystal layer 114 is provided in the region surrounded by the sealing material.

In the intelligent reflecting surface 100a, radio waves are incident from the dielectric substrate 104 side, the radio waves are reflected by the patch electrode 108, and the radio waves are emitted from the dielectric substrate 104 side. Therefore, it is preferable that no wiring or transistors that could obstruct the propagation of radio waves are arranged between the dielectric substrate 104 and the patch electrode 108. The light-emitting element 220 emits light from the dielectric substrate 104 side. Therefore, it is preferable that no wiring and transistors that may cause a decrease in the aperture ratio of the pixel 240 are arranged between the dielectric substrate 104 and the light-emitting region of the light-emitting element 220.

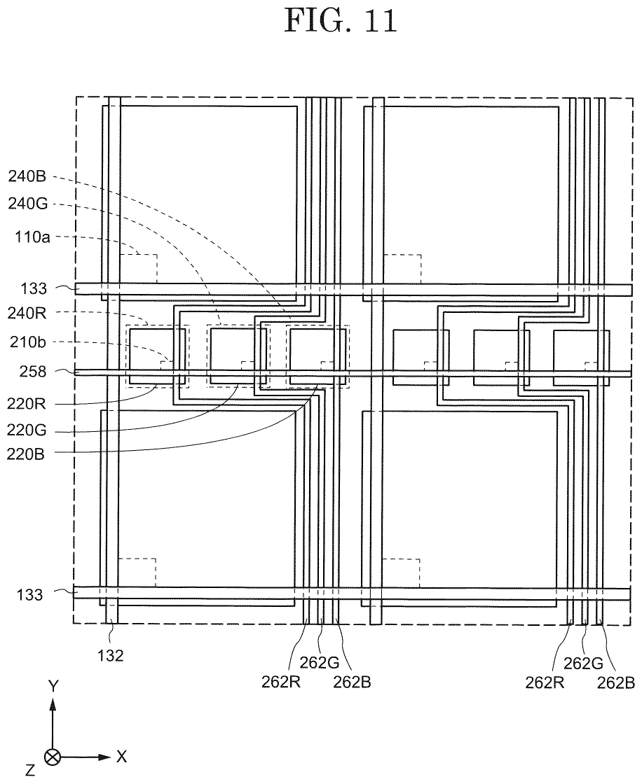

FIG. 11 is a layout diagram of a reflector plate unit cell 121 and the pixel 240 when viewed from the dielectric substrate 104 side. In FIG. 11, the transistor 210b, the patch electrode 108, the scan line 133, and the signal line 132 are shown as the reflector plate unit cell 121. Light-emitting elements 220R, 220G, and 220B, the scan line 258, and signal lines 262R, 262G, and 262B are shown as the pixels 240R, 240G, and 240B. These transistors and wiring are part of the transistors and wiring forming the intelligent reflecting surface 100a, and illustration of other configurations is omitted.

In the pixel 240, it is preferable that the scan line 258 and the signal lines 262R, 262G, and 262B are provided so as not to overlap the patch electrode 108. It is preferable that the scan line 258 and the signal lines 262R, 262G, and 262B are provided in the gap between adjacent patch electrodes 108. The signal lines 262G and 262B include a region extending in the Y-axis direction and a region extending in the X-axis direction. As described above, by bending and arranging the signal lines 262G and 262B in the gap between adjacent patch electrodes 108, the aperture ratio of the pixel 240 can be improved, and the radio wave reflection characteristics can be improved.

According to the intelligent reflecting surface 100a according to one embodiment of the present invention, the light-emitting element 220 is provided in a region where the adjacent reflective elements 102 are separated from each other. This makes it possible to form a display region in the region where the reflective elements 102 are separated from each other. As a result, the radio wave reflector plate 120 and a display region including the plurality of pixels 240 can be formed on the same substrate. Since the radio wave reflecting function and the image display function can be integrated, space can be saved compared with the case where both the intelligent reflecting surface and the display device are installed. In addition, the region where the pixel 240 is provided is smaller than the region where the reflector plate unit cell 121 is provided. Therefore, the reflection of radio waves by the pixel 240 can be suppressed. Therefore, the influence of the intelligent reflecting surface 100a on the control of the communication area can be reduced.

### 4. Configuration of Intelligent Reflecting Surface 100b

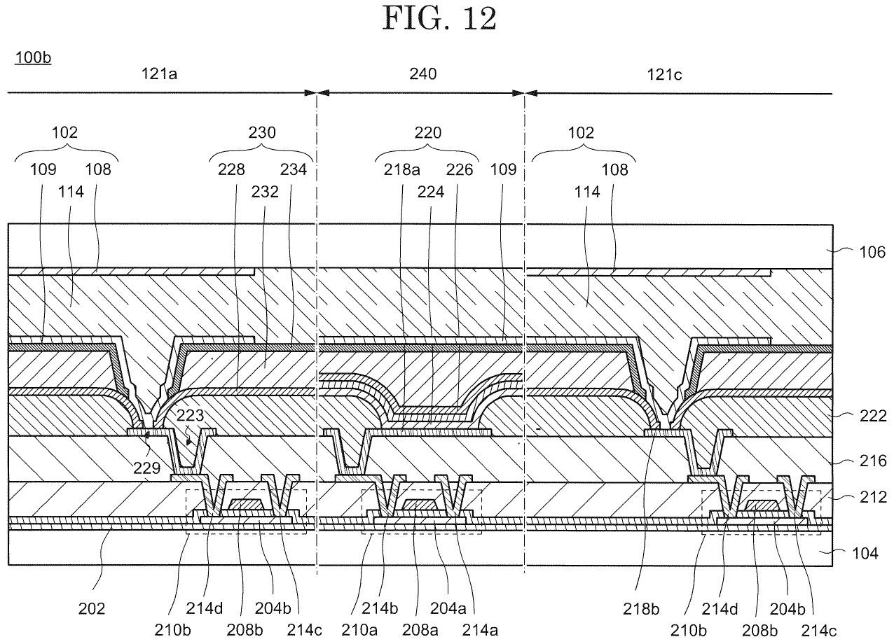

FIG. 12 is an example of a cross-sectional view of an intelligent reflecting surface 100b having the radio wave reflecting function and the image display function. In FIG. 12, the intelligent reflecting surface 100b in which the radio wave incident surface/reflecting surface is on the counter substrate 106 side and the light-emitting element 220 is also emitted from the counter substrate 106 side (top emission) will be described. In addition, FIG. 12 shows a region where the pixel 240 is provided between the regions where the adjacent reflector plate unit cells 121 are provided. As shown in FIG. 12, the reflective elements 102a and 102b, and the light-emitting element 220 are provided on the same substrate in the region where the reflective element 102a and the reflective element 102b are separated from each other. A transistor for controlling the reflective element 102 and a transistor for controlling the light-emitting element 220 are also provided on the same substrate. The layout of the reflective element 102 and the light-emitting element 220 is the same as in FIG. 7. In the following description, differences from the configuration of the light-emitting element 220 and the configuration of the reflective element 102 of the intelligent reflecting surface 100a will be described.

### 4-1. Configuration of Pixel

In the pixel 240, a drain electrode of the transistor 210a is connected to the pixel electrode 218a of the light-emitting element 220. In the intelligent reflecting surface 100b shown in FIG. 12, a top emission type light-emitting element 220 is used. Therefore, a metal film with high light reflectance is used as the pixel electrode 218a, or a stacked structure of a transparent conductive layer with a high work function such as an indium oxide-based transparent conductive layer (for example, ITO) or a zinc oxide-based transparent conductive layer (for example, IZO, ZnO) and a metal film is used. On the other hand, the transparent conductive layer described above is used as the common electrode 226. This allows the light emitted from the light-emitting element 220 to be emitted from the counter substrate 106 side.

### 4-2. Configuration of Reflective Element

In the intelligent reflecting surface 100b shown in FIG. 12, since the radio wave incident surface/reflecting surface is on the counter substrate 106 side, the patch electrode 108 is provided on the counter substrate 106 side. The patch electrode 108 functions as a common electrode with respect to the liquid crystal. The drain electrode 214d of the transistor 210b is connected to the drive electrode 109. The drive electrode 109 is arranged to face the rectangular shape of the patch electrode 108. The drive electrode 109 of each reflective element 102 is provided independently, and adjacent drive electrodes 109 are not connected to each other. The drive electrode 109 is GND for radio waves. This allows radio waves to be incident from the counter substrate 106 side, reflected by the reflective element 102, and emitted from the counter substrate 106 side.

The size of the patch electrode 108 and the drive electrode 109 is larger than the size of the pixel electrode. While the size of the patch electrode 108 is several mm², the size of the pixel electrode and the size of the drive electrode 109 are several tens of μm² to several hundreds of μm².In FIG. 12, to emit the light-emitting element 220 from the counter substrate 106 side, it is preferable that the patch electrode 108 and the drive electrode 109 do not overlap the light-emitting element 220.

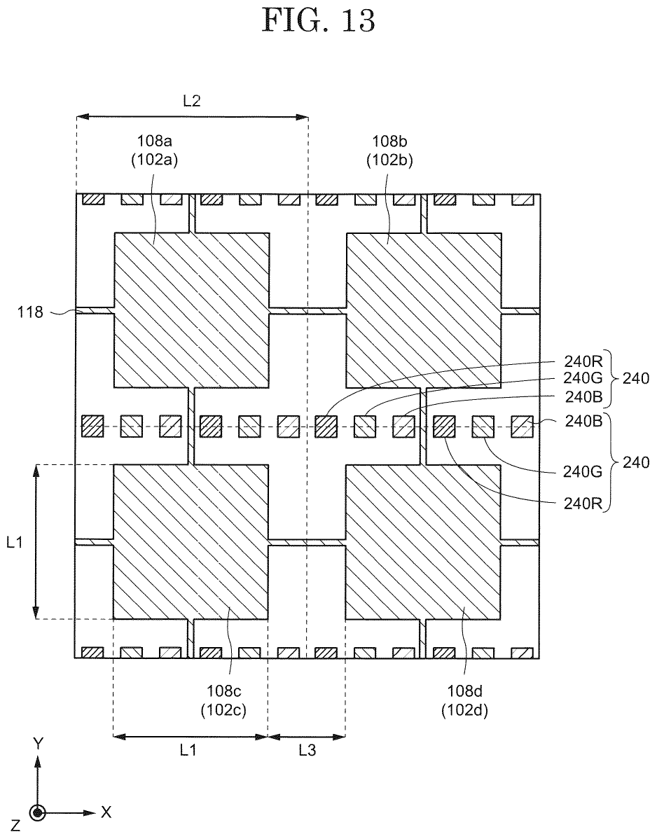

FIG. 13 is a plan view when the patch electrode 108 and the pixels 240R, 240G, and 240B are viewed from the counter substrate 106 side. The patch electrode 108 is formed in a rectangular shape similar to the intelligent reflecting surface 100a, but adjacent patch electrodes 108 are connected by the first wiring 118. It is preferable that the pixels 240R, 240G, and 240B are arranged so as not to overlap the first wiring 118 in the gap L3 between adjacent patch electrodes 108. As shown in FIG. 13, it is preferable to arrange the pixels 240R, 240G, and 240B and the pixels 240R, 240G, and 240B to sandwich the first wiring 118 extending in the Y-axis direction. By using the top emission type light-emitting element 220, transistors and wiring can be arranged below the drive electrode 109 which is GND for radio waves (on the side opposite to the radio wave incident direction). As a result, the influence on reflection characteristics caused by transistors and wiring can be reduced. However, since adjacent drive electrodes 109 are not connected to each other, there is a concern that a gap occurs in the drive electrode 109 which is GND for radio waves, and reflection characteristics may deteriorate. Therefore, as shown in FIG. 12, by overlapping the common electrode 226 and the drive electrode 109, the gap of the drive electrode 109 which is GND for radio waves can be filled.

According to the intelligent reflecting surface 100b according to one embodiment of the present invention, similar to the intelligent reflecting surface 100a, a display region can be formed in a region where adjacent reflective elements 102 are separated from each other. As a result, the radio wave reflector plate 120 and a display region including the plurality of pixels 240 can be formed on the same substrate. Since the radio wave reflecting function and the image display function can be integrated, space can be saved compared with a case where both an intelligent reflecting surface and a display device are installed. In addition, the region where the pixel 240 is provided is smaller than the region where the reflector plate unit cell 121 is provided. Therefore, the reflection of radio waves by the pixel 240 can be suppressed. Therefore, the influence of the intelligent reflecting surface 100a on the control of the communication area can be reduced.

### Modifications

The present invention is not limited to the embodiments described above and includes various other modifications. For example, the embodiments described above have been described in detail for easy understanding of the present invention and are not necessarily limited to those having all the configurations described. Other configurations may be added, deleted, or replaced for part of the configurations of the embodiments and part of the modifications described below. The modifications will be described below.

### First Modification

In FIG. 12, the intelligent reflecting surface 100b in which the radio wave incident surface/reflecting surface is on the counter substrate 106 side and the light-emitting element 220 is also emitted from the counter substrate 106 side (top emission) has been described. The case in which the radio wave incident surface/reflecting surface is on the counter substrate 106 side and the light-emitting element 220 is emitted from the dielectric substrate 104 side (bottom emission) will be described as a modification of FIG. 12.

In the intelligent reflecting surface 100b shown in FIG. 12, a bottom emission type light-emitting element 220 is used. Therefore, a metal film with high light reflectance is used as the common electrode 226, or a stacked structure of a transparent conductive layer with a high work function such as an indium oxide-based transparent conductive layer (for example, ITO) or a zinc oxide-based transparent conductive layer (for example, IZO, ZnO) and a metal film is used. On the other hand, the transparent conductive layer described above is used as the pixel electrode 218a. This allows the light emitted from the light-emitting element 220 to be emitted from the dielectric substrate 104 side. In addition, since the reflector plate unit cell 121 is as described in FIG. 12, a detailed description will be omitted.

In the case where the radio wave incident surface/reflecting surface is on the counter substrate 106 side and the light-emitting element 220 is emitted from the dielectric substrate 104 side (bottom emission), the plan view when the patch electrode 108 and the pixels 240R, 240G, and 240B are viewed from the counter substrate 106 side is the same as FIG. 11. The pixels 240R, 240G, and 240B may be arranged in any manner as long as the light-emitting region of the light-emitting element 220 does not overlap wiring or electrodes forming the pixel circuit, or wiring or electrodes forming the reflective element.

According to the intelligent reflecting surface described in the First Modification, similar to the intelligent reflecting surfaces 100a and 100b, a display region can be formed in a region where adjacent reflective elements 102 and reflective elements 102 are separated from each other. In addition, the radio wave incident surface/reflecting surface can be on the counter substrate 106 side, and the light-emitting element 220 can be emitted from the dielectric substrate 104 side. This makes it possible to make the radio wave incident surface/reflecting surface different from the surface on which the light-emitting element 220 emits light. As a result, the reflection of radio waves by the pixel 240 can be suppressed. Therefore, the influence of the intelligent reflecting surface 100a on the control of the communication area can be reduced. Other configurations are similar to those of the intelligent reflecting surfaces 100a and 100b, so that the intelligent reflecting surface described in the First Modification also achieves similar effects.

### Second Modification

The layout of the pixel 240 shown in the present embodiment is merely an example, and the pixel 240 may be arranged in any manner as long as the light-emitting region of the light-emitting element 220 does not overlap wiring or electrodes forming the pixel circuit, or wiring or electrodes forming the reflective element. The layout of the pixels 240R, 240G, and 240B shown in FIG. 13 may be applied to the intelligent reflecting surface 100a shown in FIG. 9. Alternatively, the layout of the pixels 240R, 240G, and 240B shown in FIG. 7 may be applied to the intelligent reflecting surface 100b shown in FIG. 12. Furthermore, although the examples in which the pixels 240R, 240G, and 240B are arranged along the X-axis direction have been described in FIG. 7 and FIG. 13, the pixels 240R, 240G, and 240B may be arranged along the Y-axis direction, or the pixels 240R, 240G, and 240B may be arranged along both the X-axis direction and the Y-axis direction.

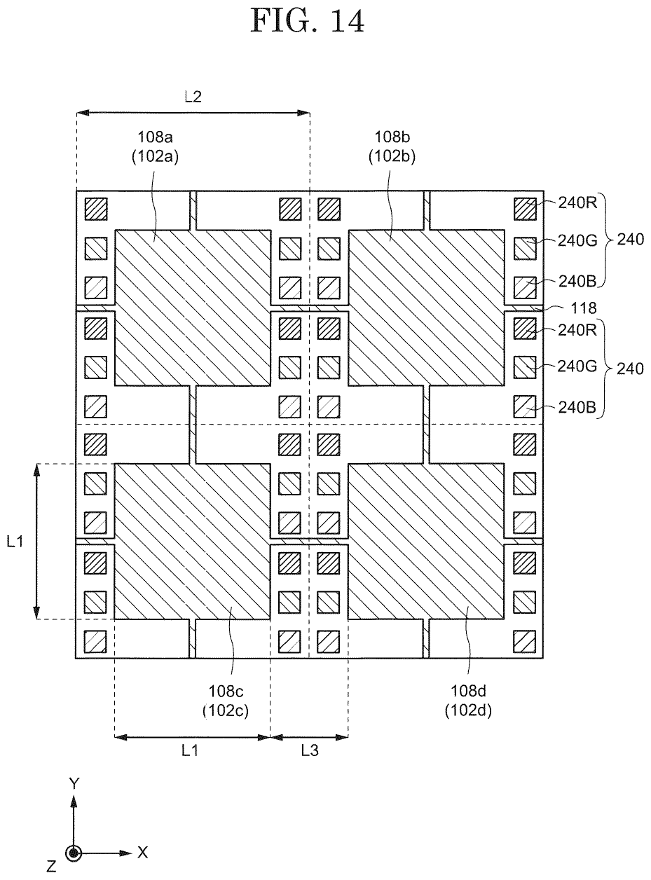

In addition, although the layout in which the pixels 240R, 240G, and 240B are provided in one row has been described in FIG. 7 and FIG. 13, the pixels may be provided in a plurality of rows or columns. FIG. 14 is a plan view when the patch electrode 108 and the pixels 240R, 240G, and 240B are viewed from the counter substrate 106 side. It is preferable that the pixels 240R, 240G, and 240B are arranged so as not to overlap the first wiring 118 in the gap L3 between adjacent patch electrodes 108. As shown in FIG. 14, it is preferable to arrange the pixels 240R, 240G, and 240B and the pixels 240R, 240G, and 240B to sandwich the first wiring 118 extending in the X-axis direction. FIG. 14 shows an example in which the pixels 240R, 240G, and 240B are provided in two rows along the X-axis direction.

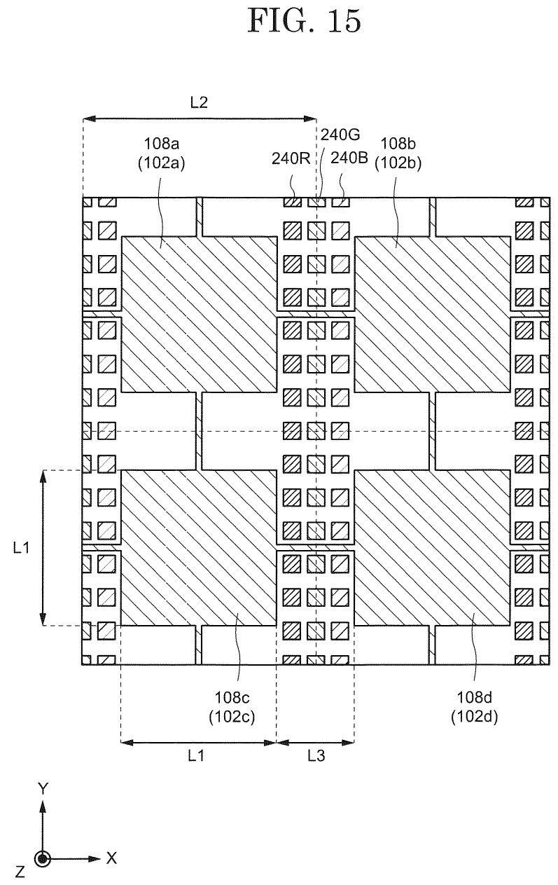

FIG. 15 is a plan view when the patch electrode 108 and the pixels 240R, 240G, and 240B are viewed from the counter substrate 106 side. FIG. 15 shows a column of pixels 240R, a column of pixels 240G, and a column of pixels 240B in the gap L3 between adjacent patch electrodes 108. As a result, a higher-definition image display function can be applied to the intelligent reflecting surface 100.

The intelligent reflecting surface 100 exemplified as one embodiment of the present invention can be appropriately combined and implemented as long as no contradiction is caused. Furthermore, the addition, deletion, or design change of components, or the addition, deletion, or condition change of processes as appropriate by those skilled in the art based on the method for driving the intelligent reflecting surface 100 disclosed in the present specification and drawings are also included in the scope of the present invention as long as they are provided with the gist of the present invention.

Furthermore, it is understood that, even if the effect is different from those provided by each of the embodiments disclosed in the present specification, the effect obvious from the description in the specification or easily predicted by persons ordinarily skilled in the art is apparently derived from the present invention.

What is claimed is:

1. An intelligent reflecting surface comprising:
a plurality of reflective elements arranged at predetermined intervals in a first direction and a second direction intersecting the first direction; and
a plurality of light-emitting elements arranged in a region between the plurality of reflective elements,
wherein each of the plurality of reflective elements comprises:
a patch electrode arranged on a first substrate;
a ground electrode arranged on a second substrate facing the first substrate and superimposed on the patch electrode; and
a liquid crystal layer between the patch electrode and the ground electrode,
wherein each of the plurality light-emitting elements comprises:
a first electrode provided on the first substrate;
a second electrode provided on the first substrate; and
an organic light-emitting layer sandwiched between the first electrode and the second electrode.

2. The intelligent reflecting surface according to claim 1, further comprising:
a first transistor and a second transistor arranged on the first substrate,
wherein the first transistor is connected to the patch electrode, and the second transistor is connected to the first electrode.

3. The intelligent reflecting surface according to claim 1, wherein
the first electrode is light-transmissive and functions as a pixel electrode, and
the second electrode reflects light and functions as a common electrode.

4. The intelligent reflecting surface according to claim 1, wherein
a size of the patch electrode is larger than a size of the first electrode.

5. The intelligent reflecting surface according to claim 1, wherein
the ground electrode overlaps the light-emitting element.

6. The intelligent reflecting surface according to claim 1, wherein
the second electrode does not overlap the patch electrode.

7. An intelligent reflecting surface comprising:
a plurality of reflective elements arranged at predetermined intervals in a first direction and a second direction intersecting the first direction; and
a plurality of light-emitting elements arranged in a region between the plurality of reflective elements,
wherein each of the plurality of reflective elements comprises:
a drive electrode arranged on a first substrate; and
a patch electrode arranged on a second substrate facing the first substrate and superimposed on the drive electrode; and
a liquid crystal layer between the drive electrode and the patch electrode,
wherein each of the plurality of light-emitting elements comprises:
a first electrode provided on the first substrate;
a second electrode provided on the first substrate; and
an organic light-emitting layer sandwiched between the first electrode and the second electrode.

8. The intelligent reflecting surface according to claim 7, further comprising:
a first transistor and a second transistor arranged on the first substrate,
wherein the first transistor is connected to the drive electrode, and the second transistor is connected to the first electrode.

9. The intelligent reflecting surface according to claim 7, wherein
the first electrode reflects light and functions as a pixel electrode, and
the second electrode is light-transmissive and functions as a common electrode.

10. The intelligent reflecting surface according to claim 7, wherein
the first electrode is light-transmissive and functions as a pixel electrode, and
the second electrode reflects light and functions as a common electrode.

11. The intelligent reflecting surface according to claim 7, wherein
a size of the drive electrode and a size of the patch electrode are larger than a size of the first electrode.

12. The intelligent reflecting surface according to claim 7, wherein
the drive electrode and the patch electrode do not overlap the plurality of light-emitting elements.

13. The intelligent reflecting surface according to claim 7, wherein
the patch electrode is connected to an adjacent patch electrode via a first wiring, and
the first wiring does not overlap the plurality of light-emitting elements.
